(19) United States
(12) Patent Application Publication
(10) Pub. No.: US 2010/0090348 A1
(43) Pub. Date: Apr. 15, 2010

(54) Single-Sided Trench Contact Window

(76) Inventors: Inho Park, Dresden (DE); Hans-Peter Moll, Dresden (DE); Gouri Sankar Kar, Dresden (DE); Lars Heineck, Radebehl (DE)

Correspondence Address: COATS & BENNETT/QIMONDA, 1400 CRESCENT GREEN, SUITE 300, CARY, NC, 27518, US

(21) Appl. No.: 12/249,104

(22) Filed: Oct. 10, 2008

(51) Int. Cl. H01L 23/48; H01L 21/76; H01L 21/82

(52) U.S. Cl. 257/773; 438/424; 438/423; 438/128; 438/429; 257/E23.168; 257/E21.575; 257/E21.24

(57) ABSTRACT

An integrated circuit is manufactured from a semiconductor substrate having trenches with first and second sidewalls facing each other and a conductive line arranged in a bottom region of the trenches. At least the bottom region of the trenches is lined with an insulative material between the conductive line and the substrate. A first sacrificial layer is formed above the conductive line adjacent the first and second sidewalls. The trenches are filled with one or more additional sacrificial layers having a different etch selectivity than the first sacrificial layer. A portion of the one or more additional sacrificial layers and a portion of the insulative material are selectively removed to the first sacrificial layer so that the substrate is exposed below the first sacrificial layer along the first trench sidewalls and covered by the insulative material along the second trench sidewalls.

### TECHNICAL FIELD

The present invention generally relates to semiconductor devices, and more particularly relates to forming interconnects between semiconductor devices.

### BACKGROUND

Integrated circuits (ICs) are typically manufactured using semiconductor substrates. Trenches can be formed in the substrates for improving density of the ICs, e.g., by burying wiring, transistors, storage capacitors and/or other structures in the substrate. In one use, trenches are filled with conductive material to form electrical connections with conductive lines buried below or adjacent the trenches. In memory devices, the buried lines can be used as bit and/or word lines. For example, a buried bit line can be formed below a trench in the substrate. The trench is then filled with a conductive material such as polysilicon for connecting the buried bit line to the circuitry above. The conductive material is encapsulated with an insulative liner to separate the conductive material from the surrounding substrate. A recess is formed in the conductive material along one of the trench sidewalls to expose a part of the encapsulation liner. The exposed part of the encapsulation liner is removed to form a contact window with the adjacent substrate. An electrical connection can be formed between the conductive material in the trench and the underlying bit line via the contact window, e.g., by out-diffusing dopants into the exposed substrate through the contact window. The encapsulation material disposed along the opposing trench sidewall remains fully intact so that the conductive material is not inadvertently shorted to an adjacent buried bit line.

Single-sided contact windows are difficult to form near the bottom of a trench, particularly when the trench has a relatively high aspect ratio (e.g., a depth-to-width ratio greater than 3). At these dimensions, conventional approaches for forming a single-sided contact window in the bottom part of a trench become impractical and unreliable. For example, one conventional approach for forming a single-sided contact window in a low aspect ratio trench involves lining the trench bottom with an insulative encapsulation layer. The trench is then filled with polysilicon and recessed. A transfer liner such as amorphous silicon is formed in the recess on the polysilicon and implanted at an angle so that only part of the liner is doped. The un-doped part of the transfer liner is removed, exposing some of the underlying polysilicon. The remaining doped part of the liner is used as a mask for removing the polysilicon from one side of the trench. The polysilicon is removed using a timed etch process that directly transfers the shape of the doped liner into the polysilicon-filled trench. However, some of the polysilicon remains on the trench sidewall where the contact window is to be formed when the timed etch process is too short. This residual polysilicon blocks the formation of the single-sided contact window by protecting the underlying encapsulation layer during subsequent processing. If the timed etch process is too long, the substrate is undesirably etched away in the region where the polysilicon is removed, distorting the shape of the trench.

These problems and others become worse with high aspect ratio trenches. For example, an extremely low implant angle of a few degrees is needed to form a transfer liner deep in a high aspect ratio trench. Low implant angles cause implant scattering and other adverse affects that make it difficult to reliably pattern a structure in the liner. Thus, the liner must be formed much closer to the substrate surface to allow for a wider implant angle. However, it becomes nearly impossible to directly transfer the patterned shape of the liner deep into the trench by etching the trench polysilicon because polysilicon etch processes are difficult to reliably control over long distances as described above.

### SUMMARY

In one embodiment, an integrated circuit is manufactured from a semiconductor substrate having trenches with first and second sidewalls facing each other and a conductive line arranged in a bottom region of the trenches. At least the bottom region of the trenches is lined with an insulative material between the conductive line and the substrate. A first sacrificial layer is formed above the conductive line adjacent the first and second sidewalls. The trenches are filled with one or more additional sacrificial layers having a different etch selectivity than the first sacrificial layer. A portion of the one or more additional sacrificial layers and a portion of the insulative material are selectively removed to the first sacrificial layer so that the substrate is exposed below the first sacrificial layer along the first trench sidewalls and covered by the insulative material along the second trench sidewalls.

Of course, the present invention is not limited to the above features and advantages. Those skilled in the art will recognize additional features and advantages upon reading the following detailed description, and upon viewing the accompanying drawings.

### BRIEF DESCRIPTION OF THE DRAWINGS

FIGS. 1A-1M are cross-sectional views of a semiconductor substrate during different stages of a method for forming a single-sided contact window in a trench.

FIGS. 2A-2I are cross-sectional views of a semiconductor substrate during different stages of another method for forming a single-sided contact window in a trench.

### DETAILED DESCRIPTION

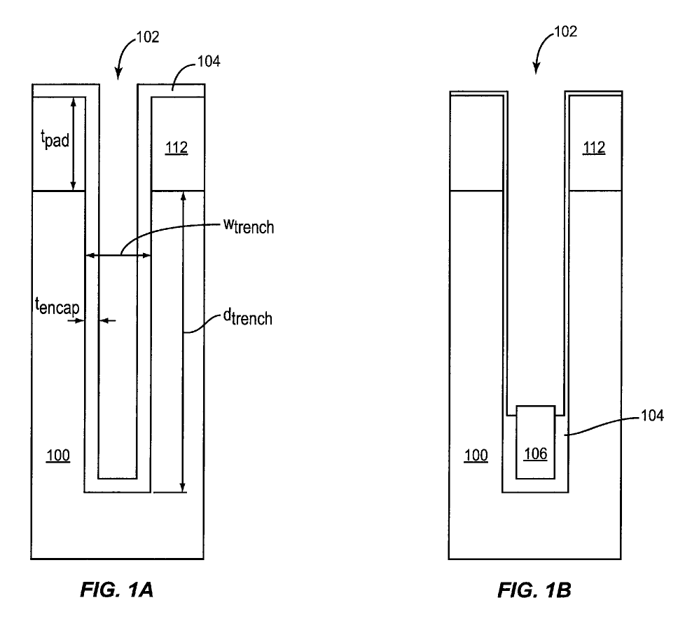

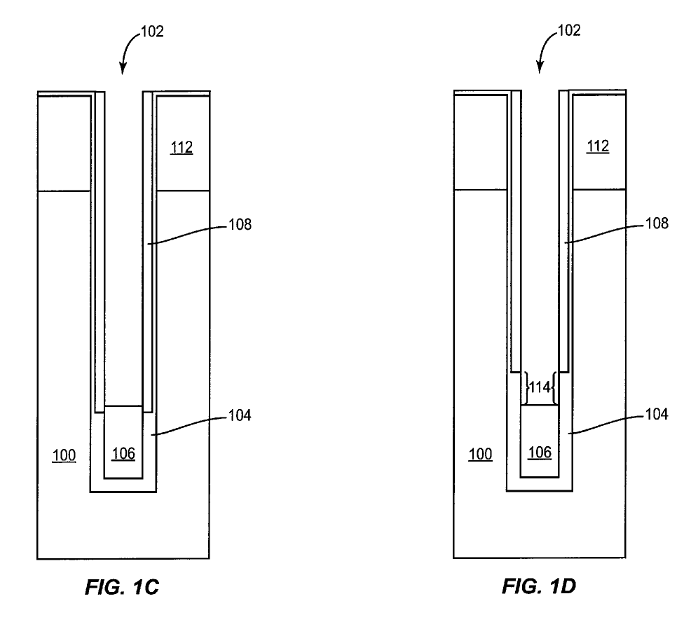

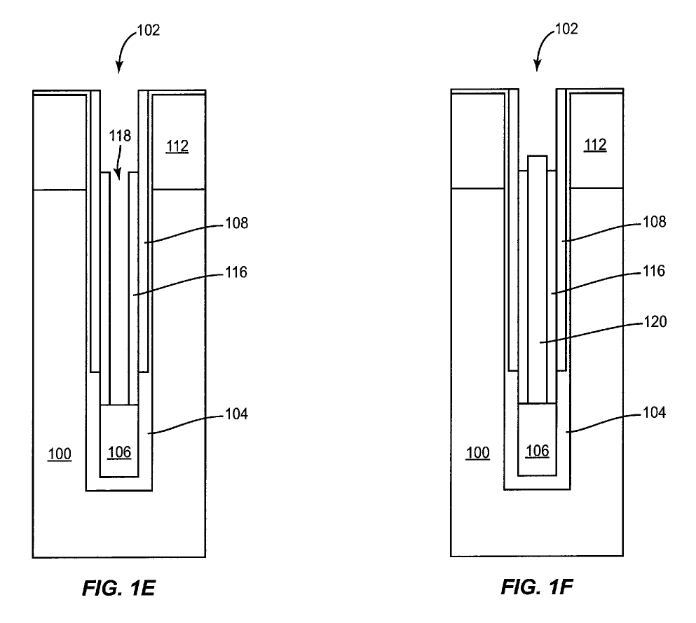

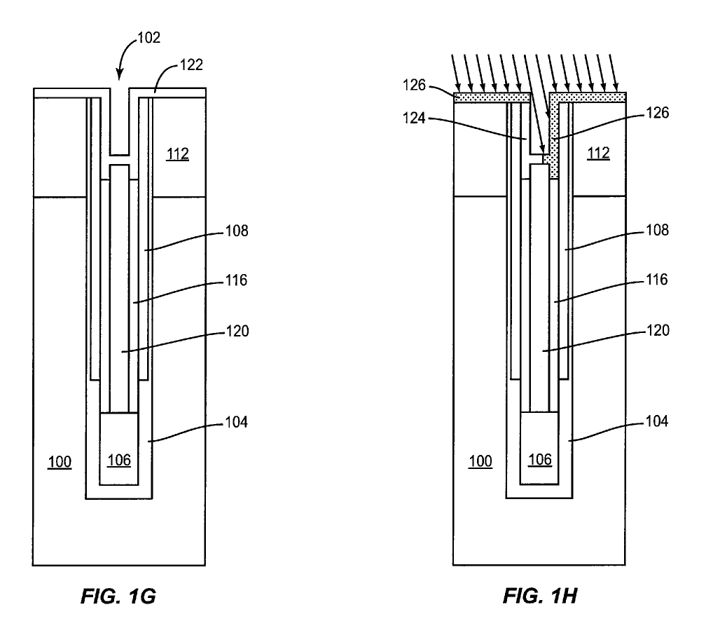

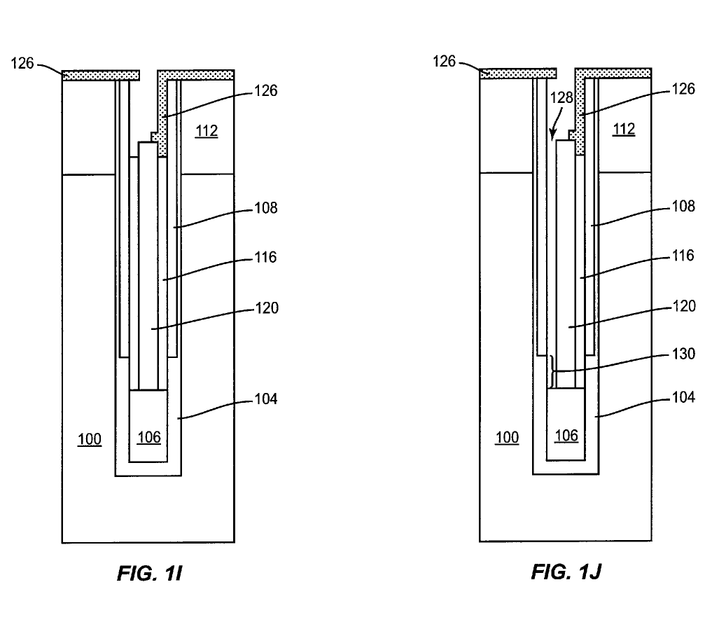

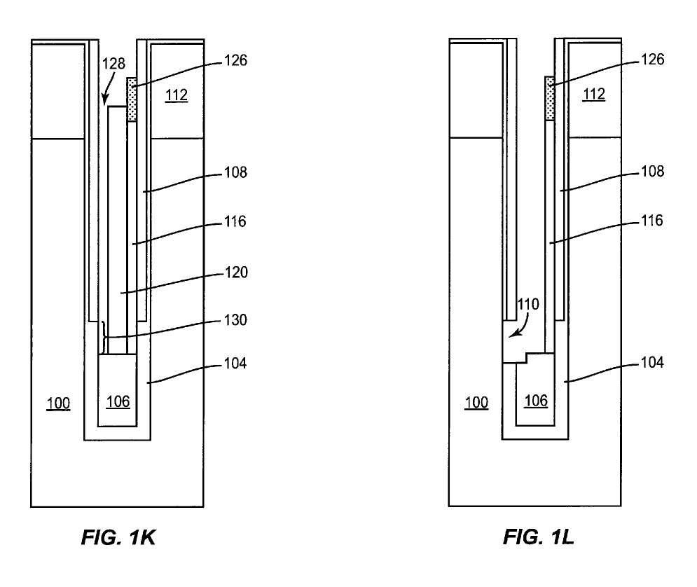

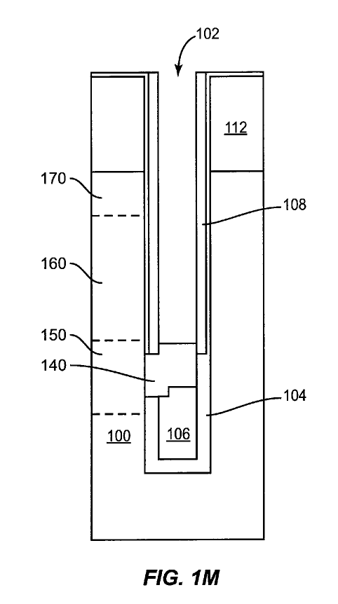

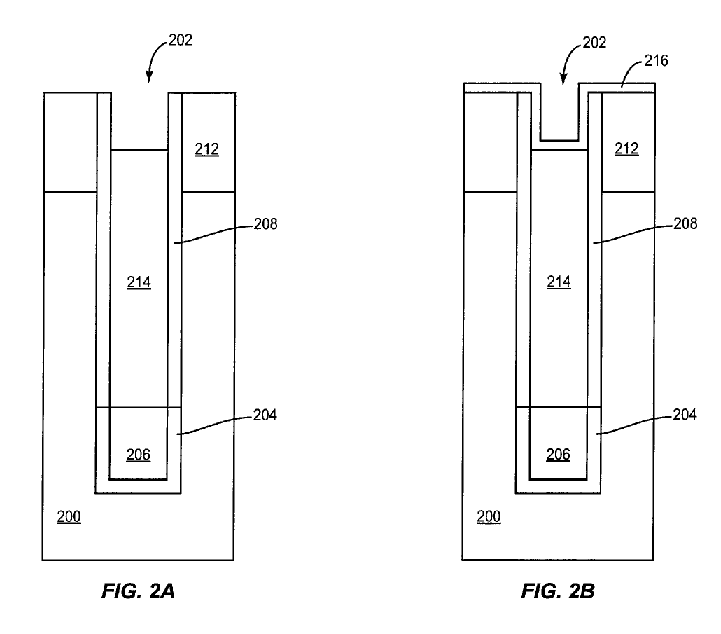

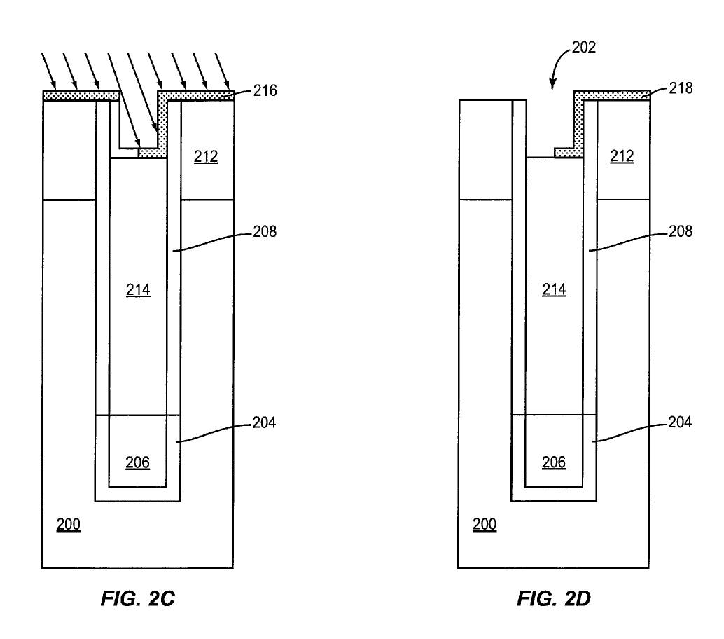

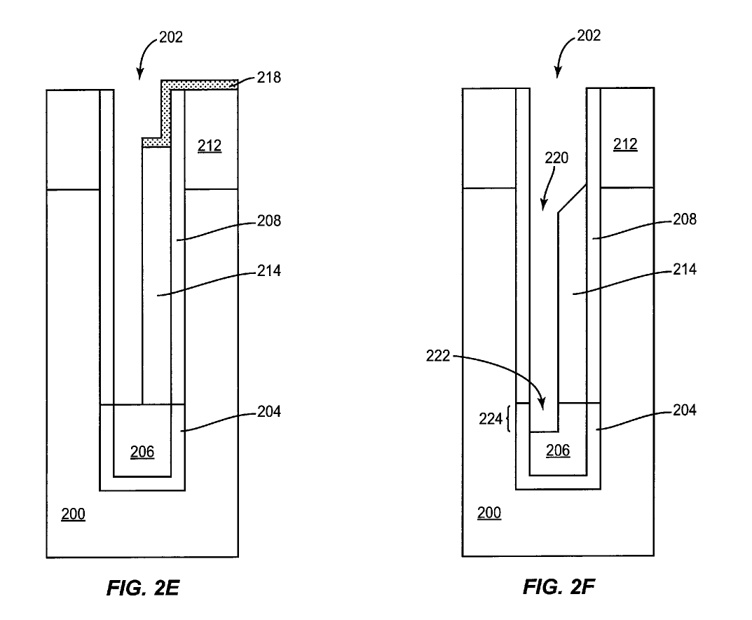

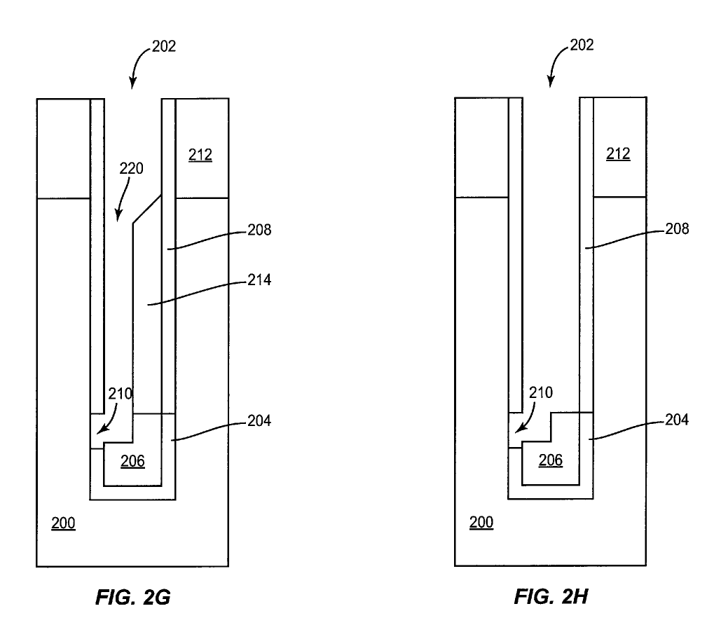

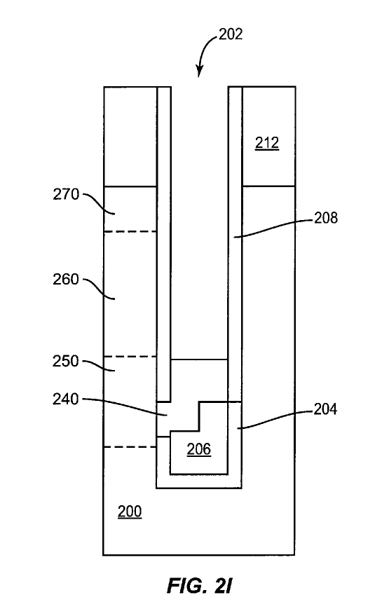

FIGS. 1A-1M illustrate an embodiment of a semiconductor substrate 100 during formation of a single-sided contact window 110 in a trench 102. FIGS. 2A-2I illustrate another embodiment of a semiconductor substrate 200 during formation of a single-sided contact window 210 in a trench 202. In each embodiment, the trenches 102, 202 are formed in semiconductor substrates 100, 200 and have sidewalls and a bottom region. The trenches 102, 202 can be formed using any suitable technique, e.g., using techniques such as anisotropic RIE (reactive ion etching) to form substantially vertical sidewalls or other etching techniques to form sloped or tapered sidewalls. An encapsulation layer 104, 204 is arranged adjacent the sidewalls at least in the bottom region of the trenches 102, 202 and a conductive line 106, 206 is arranged in the bottom region of the trenches 102, 202 adjacent to the encapsulation layer 104, 204. The encapsulation layer 104, 204 separates the conductive line 106, 206 from the surrounding substrate 100, 200. A protection liner 108, 208 is arranged along the trench sidewalls above the conductive line 106, 206. A portion of the encapsulation layer 104, 204 is removed along one of the trench sidewalls below the protection liner 108, 208 to form a single-sided contact window 110, 210. The single-sided contact window 110, 210 exposes the substrate 100, 200 on one side of the trenches 102, 202. An electrical connection can be formed between the exposed portion of the substrate 100, 200 and the conductive line 106, 206. The trenches 102, 202 can be used to form many different types of buried structures in ICs, e.g., wiring, transistors, storage capacitors and/or other structures.

The shape of the single-sided contact window 110, 210 formed in the trenches 102, 202 is patterned in an upper part of the trenches 102, 202 and transferred deep into the trenches 102, 202 based on the etch selectivity of different sacrificial layers provided in the trenches 102, 202. This way, a wider implant angle can be used to create the patterned transfer structure closer to the substrate surface. Moreover, the patterned structure is transferred deep into the trenches 102, 202 using a controllable and reliable process that depends on the etch selectivity of the sacrificial layers.

Turning to the embodiment shown in FIGS. 1A-1M in more detail, a pad nitride layer 112 is applied to the substrate 100 after trench formation and the sidewalls and bottom of the trench 100 are lined with the encapsulation layer 104 as shown in FIG. 1A. The encapsulation layer 104 can be provided using any suitable technique, e.g., by growing and depositing an oxide layer along the sidewalls and bottom of the trench 100. In one embodiment, the trench 100 has a depth (d_{trench}) of approximately 260 nm and a width (w_{trench}) of approximately 53 nm before the encapsulation layer 104 is formed. According to this embodiment, the encapsulation layer 104 has a thickness (t_{encap}) of approximately 10 nm, reducing the trench width to about 33 nm. The pad nitride layer 112 can have a thickness (t_{pad}) of approximately 10 nm, extending the trench depth to about 400 nm. Thus, the lined trench 100 has an aspect ratio of approximately twelve (400 nm/33 nm) according to this embodiment (including the pad layer thickness). The trench 100 and layers 104, 112 may have other dimensions, altering the aspect ratio of the trench 100. In general, the trench 100 preferably has an aspect ratio greater than or equal to 3.

The trench 100 is then filled with a conductive material, e.g., polysilicon and recessed to form a conductive line 106 as shown in FIG. 1B. The encapsulation layer 104 can be thinned along the trench sidewalls above the conductive line 106 also as shown in FIG. 1B, e.g., to a thickness of approximately 3 nm or removed altogether. In each case, the protection liner 108 is then formed above the conductive line 106 along the trench sidewalls as shown in FIG. 1C. The protection liner 108 is formed adjacent the encapsulation layer 104 if not removed above the conductive line 106. Otherwise, the protection layer 108 directly contacts the substrate 100 along the trench sidewalls. In one embodiment, the protection liner 108 is a SiN liner having a thickness of approximately 7 nm that is deposited along the trench sidewalls, e.g., using a CVD (chemical vapor deposition) process.

The conductive line 106 is further recessed to expose a lower part 114 of the encapsulation layer 104 between the conductive line 106 and protection liner 108 as shown in FIG. 1D. The exposed lower region 114 of the encapsulation layer 104 is not covered by either the conductive material 106 or the protection liner 108. This structural feature is subsequently utilized to open the contact window 110 in the encapsulation layer 104 on one side of the trench 100 as will be described in more detail later.

Next, a spacer 116 is formed above the conductive line 106 along the trench sidewalls adjacent the protection liner 108 and the exposed portion 114 of the encapsulation layer 104 as shown in FIG. 1E. In one embodiment, the spacer 116 is formed by depositing a TiN layer in the trench 100 and then etching the TiN layer. The TiN layer can be deposited using any suitable technique, e.g., ALD (atomic layer deposition) or CVD and anisotropically etched to form the spacer 116. The inner void 118 in the trench 100 is filled with an insulative plug 120 as shown in FIG. 1F. In one embodiment, the insulative plug 120 is formed by depositing an oxide layer using a TEOS process, planarizing the oxide layer using chemical-mechanical polishing and recessing the planarized oxide below the surface of the pad layer 112. In another embodiment, the oxide layer is etched via a reactive-ion etch process and then recessed. In yet another embodiment, the oxide layer is recessed below the surface of the pad layer 112 without first being planarized or etched. In each embodiment, the spacer 116 is recessed below the upper surface of the insulative plug 120 as shown in FIG. 1F, e.g., by etching the spacer 116.

The recessed spacer 116 and insulative plug 120 are used to form a single-sided recess in the trench 100. To this end, an un-doped amorphous silicon liner 122 is deposited on the substrate 100 as shown in FIG. 1G, e.g., using a plasma-enhanced CVD process. The amorphous silicon liner 122 is then implanted with dopants as represented by the arrows in FIG. 1H. The amorphous silicon liner 122 is implanted at an angle so that the liner 122 is doped along one of the sidewalls while remaining un-doped along the opposing sidewall. In one embodiment, dopants (e.g., BF₂) are implanted at an oblique angle ranging from approximately 10° to 30° in a direction toward one of the trench sidewalls. The un-doped part 124 of the amorphous silicon liner 122 is then removed along the opposing trench sidewall to expose the top of the spacer 116 formed along that sidewall as shown in FIG. 1I. In one embodiment, the un-doped part 124 of the amorphous silicon liner 122 is removed using a selective ammonia etch.

The exposed region of the spacer 116 is then removed along the trench sidewall where the un-doped part 126 of the amorphous silicon liner 122 was removed as shown in FIG. 1J. This creates a single-sided recess 128 in the trench 102. In one embodiment, the spacer 108 comprises TiN and is removed by wet etching (e.g., in hydrogen peroxide environment) or dry etching (e.g., in a mixture of O₂ and CO₄) the exposed portion of the spacer 116. The single-sided recess 128 exposes a part 130 of the encapsulation layer 104 below the protection liner 108 along one of the trench sidewalls. The encapsulation layer 104 remains intact and covered by the remaining portion of the spacer 116 at the opposing sidewall.

The doped amorphous silicon liner 126 can be removed at this point if desired except on the remaining portion of the spacer 116 as shown in FIG. 1K, e.g., using a RIE process. The insulative plug 120 is then removed as shown in FIG. 1L, e.g., via wet etching. Etching of the insulative plug 120 also removes the exposed part 130 of the encapsulation layer 104 below the protection liner 108 when the two materials 120, 104 have the same etch selectivity. However, the part of the spacer 116 that remains in the trench 102 along the opposing sidewall has a different etch selectivity than the insulative plug 120 and encapsulation layer 104. Accordingly, the spacer 116 remains intact during plug/encapsulation layer etching. As a result, the single-sided contact window 110 is formed in the encapsulation layer 104 below the protection liner 108 along one trench sidewall as shown in FIG. 1L.

The remainder of the spacer 116 and doped amorphous silicon liner 126 can be optionally removed. Also, the trench can be filled with a conductive material to form an electrical connection 140 between the conductive line 106 and the exposed part of the substrate 100 through the single-sided contact window 110 as shown in FIG. 1M. Excessive portions of the conductive material may be removed, e.g. by a recess etch. In one embodiment, the conductive line 106 is a bit line in a memory device and the contact window 110 forms a strap region to the adjacent substrate 100. In another embodiment, dopants can be out-diffused into the substrate 100 through the single-sided contact window 110 to form an electrical connection, e.g., with a conductive line (not shown) buried below the trench 102. In each case, the single-sided contact window 110 is used to form an electrical connection 140 between the conductive line 106 and the substrate 100.

FIGS. 2A-2I illustrate another method of forming a single-sided contact window 210. According to this embodiment, a carbon deposition and recess technique is used to form the contact window 210 along one sidewall of the trench 200. In more detail, FIG. 2A shows the trench 202 after formation of an encapsulation layer 204, conductive line 206, protection liner 208 and pad layer 212. The encapsulation layer 204, conductive line 206, protection liner 208 and pad layer 212 can be formed as previously described herein. In one embodiment, the protection liner 208 is a SiN liner deposited along the trench sidewalls, e.g., using a CVD process. The encapsulation layer 204 separates the conductive line 206 from the surrounding substrate 200. In one embodiment, the encapsulation layer 204 is removed from the trench sidewalls above the conductive line 206 as shown in FIG. 2A. Alternatively, the encapsulation layer 204 can be thinned above the conductive line 206 as described previously herein.

In each case, the trench 202 is filled with a carbon-based material 214, e.g., using a carbon CVD process and then recessed, e.g., using a dry carbon etch process. FIG. 2A shows the trench 202 after the carbon-based material 214 is recessed. The carbon-based material 214 is used to transfer a structured pattern deep into the trench 202 for opening the contact window 210 in the encapsulation layer 204 along one of the trench sidewalls. To this end, a silicon-based layer 216 is deposited on the substrate 200 as shown in FIG. 2B. In one embodiment, a SiN layer is deposited on the substrate 200. The silicon-based layer 216 is implanted with dopants as represented by the arrows in FIG. 2C. The silicon-based layer 216 is implanted at an angle so that the layer 216 is doped near one of the sidewalls, but remains un-doped near the opposing sidewall. In one embodiment, the implantation is performed at oblique angle ranging from approximately 10° to 30° in a direction toward one of the trench sidewalls. The un-doped part of the silicon-based layer 216 is then removed, exposing some of the carbon-based material 214 in the upper part of the trench 200 as shown in FIG. 2D. The rest of the carbon-based material 214 remains covered by the doped part 218 of the silicon-based layer 216.

The doped part 218 of the silicon-based layer 216 is used as a mask for forming a single-sided recess 220 in the trench by etching the unprotected part of the carbon-based material 214 in an anisotropic direction deep into the trench 202 as shown in FIG. 2E. Etching the carbon-based material 214 in this way transfers the shape of the doped silicon-based layer 218 into the trench 202 along one of the trench sidewalls, but not along the opposing sidewall. In one embodiment, the unprotected part of the carbon-based material 214 is anisotropically etched using a dry etch process, e.g., in an N₂H₂ environment. The conductive line 206 in the bottom part of the trench 202 becomes partially exposed during the carbon etch process.

The exposed part of the conductive line 206 is then etched as show in FIG. 2F to form a recess 222 in the conductive line 206. The recess 222 in the conductive line 206 exposes part 224 of the encapsulation layer 204 arranged below the protection liner 208 and adjacent the removed portion of the conductive line 206. In one embodiment, the conductive line 206 is unselectively etched to form the recess 222 so that the doped part 218 of the silicon-based layer 216 is also removed from the carbon-based material 214 as shown in FIG. 2F. The single-sided contact window 210 is then formed in the trench 202 by removing the exposed part 224 of the encapsulation layer 204 as shown in FIG. 2G, e.g., using a diluted wet etch. The remainder of the carbon-based material 214 can be removed from the trench 202 as shown in FIG. 2H, e.g., using a dry etch process. The carbon-based material 214 can be removed before or after the single-sided contact window 210 is formed in the encapsulation layer 204. The trench 202 is subsequently filled with a conductive material to form an electrical connection 240 between the conductive line 206 and the part of the substrate 200 adjacent the single-sided contact window 210 as described previously herein and shown in FIG. 2I.

In each embodiment described herein, a plurality of sacrificial layers are utilized to form the single-sided recess 128/220 deep into the trenches 102/202. The layers are sacrificial in that they facilitate the formation of the contact window 110/210 along one of the trench sidewalls, but are later removed during subsequent processing steps. For example, three sacrificial layers are used in the embodiment of FIGS. 1A-1M—the protection liner 108, spacer 116 and insulative plug 120. Two sacrificial layers are used in the embodiment of FIGS. 2A-2I—the protection liner 208 and carbon-based material 214. In each case, the sacrificial layers are used to transfer a structured pattern formed in an upper part of the trenches 102/202 deep into the trenches 102/202 so that an electrical connection 140/240 can be reliably formed between the conductive line 106/206 and the exposed substrate 100/200. The semiconductor substrate 100/200 can be used to manufacture a memory array (not shown) including an array of transistors with a lower source/drain region 150/250, an upper source/drain region 170/270 and a channel region 160/260 disposed between the upper and lower source/drain regions 150/250, 170/270 as shown in FIGS. 1M and 2I, respectively. According to this embodiment, the transistors are separated from each other by the trenches 102/202.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. A method of manufacturing an integrated circuit, comprising:
providing a substrate having trenches with first and second sidewalls facing each other and a conductive line arranged in a bottom region of the trenches, at least the bottom region of the trenches being lined with an insulative material between the conductive line and the substrate,
forming a first sacrificial layer above the conductive line adjacent the first and second sidewalls;
filling the trenches with one or more additional sacrificial layers having a different etch selectivity than the first sacrificial layer; and
removing a portion of the one or more additional sacrificial layers and a portion of the insulative material selectively to the first sacrificial layer so that the substrate is exposed below the first sacrificial layer along the first trench sidewalls and covered by the insulative material along the second trench sidewalls.

2. The method of claim 1, wherein the first sacrificial layer comprises SiN.

3. The method of claim 1, wherein the one or more additional sacrificial layers comprises TiN.

4. The method of claim 1, further comprising:
forming an amorphous silicon layer adjacent the one or more additional sacrificial layers in an upper portion of the trenches;
implanting the amorphous silicon layer in a direction toward the second trench sidewalls; and
removing an un-implanted portion of the amorphous silicon layer along the first trench sidewalls to form a single-sided transfer structure;

5. The method of claim 4, wherein removing a portion of the one or more additional sacrificial layers and a portion of the insulative material selectively to the first sacrificial layer comprises:
removing the one or more additional sacrificial layers along the first sidewalls using the single-sided transfer structure as a mask so that the second sidewalls remain covered by the one or more additional sacrificial layers; and
exposing the substrate below the first sacrificial layer along the first trench sidewalls.

6. The method of claim 1, wherein removing a portion of the one or more additional sacrificial layers and a portion of the insulative material selectively to the first sacrificial layer comprises:
forming an amorphous silicon layer adjacent the first sacrificial layer in an upper portion of the trenches;
implanting the amorphous silicon layer in a direction toward the second trench sidewalls;
removing an un-implanted portion of the amorphous silicon layer along the first trench sidewalls;
removing a first one of the additional sacrificial layers along the first sidewalls so that the first one of the additional sacrificial layers is protected along the second sidewalls by a second one of the additional sacrificial layers and the implanted portion of the amorphous silicon layer; and
exposing the substrate below the first sacrificial layer along the first trench sidewalls so that the insulative material is protected along the second sidewalls by the remaining portion of the first additional sacrificial layer.

7. The method of claim 6, wherein exposing the substrate below the first sacrificial layer along the first trench sidewalls comprises removing the insulative material along the first trench sidewalls between the first sacrificial layer and the conductive line to expose the substrate.

8. The method of claim 1, wherein the one or more additional sacrificial layers comprises a carbon-based material.

9. The method of claim 8, wherein removing a portion of the one or more additional sacrificial layers and a portion of the insulative material selectively to the first sacrificial layer comprises:
forming a liner on the carbon-based material in an upper part of the trenches;
doping the liner in a direction toward the second sidewalls;
removing an un-doped portion of the liner;
etching the carbon-based material in an anisotropic direction into the trenches using the doped portion of the liner as a mask to expose an upper part of the conductive line near the first trench sidewalls;
removing the upper part of the conductive line near the first trench sidewalls so that a portion of the insulative material is exposed; and
removing the exposed portion of the insulative material.

10. The method of claim 9, wherein forming a liner on the carbon-based material in an upper part of the trenches comprises:
recessing the carbon-based material into a depth of the trenches; and
forming a SiN liner on the recessed carbon-based material.

11. The method of claim 9, further comprising removing the remainder of the carbon-based material from the trenches after the upper part of the conductive line is removed.

12. The method of claim 1, further comprising forming an electrical connection between the conductive line and the exposed portion of the substrate.

13. The method of claim 12, wherein forming the electrical connection comprises:
filling a conductive material into the removed portion of the one or more additional layers and the removed portion of the insulative material; and
recessing the conductive material.

14. A method of manufacturing a memory array comprising an array of transistors with an upper source/drain region, a lower source/drain region and a channel region disposed between the upper and lower source/drain regions, the transistors separated from each other by trenches, the method comprising:
forming a bit line in a bottom region of at least one of the trenches arranged in a substrate, the at least one trench having an encapsulation layer disposed between the bit line and the substrate;
forming a protection liner above the bit line on sidewalls of the at least one trench;
filling the at least one trench with a sacrificial material;
recessing the sacrificial material into the at least one trench;
depositing a silicon-based layer in the recess;
single-sided structuring the silicon-based layer;
etching the sacrificial material using the structured silicon-based layer as a mask to expose the protection liner along one of the sidewalls and an upper portion of the bit line;
removing a portion of the encapsulation layer below the exposed protection liner to expose the lower source/drain region of at least one of the transistors; and
forming an electrical connection between the bit line and the lower source/drain region of at least one of the transistors.

15. The method of claim 14, wherein single-sided structuring the silicon-based layer comprises implanting the silicon-based layer in a direction toward one of the sidewalls of the at least one trench.

16. The method of claim 14, wherein etching the sacrificial material using the structured silicon-based layer as a mask comprises etching the sacrificial material in an anisotropic direction into the at least one trench using the structured silicon-based layer as a mask.

17. A method of manufacturing an integrated circuit, comprising:
providing a substrate with a trench filled to a recess depth, the filled trench comprising an encapsulation layer disposed between a conductive line arranged in a bottom region of the trench and sidewalls of the trench, a protection liner arranged adjacent to the encapsulation layer above the conductive line, and a fill material arranged adjacent to the protection liner above the conductive line;
forming a single-sided structure from a silicon-based layer deposited on the substrate;
forming a single-sided recess in the trench using the single-sided structure as a mask, the single-sided recess extending vertically into the trench to the conductive line;
removing a portion of the encapsulation layer through the single-sided recess to expose a portion of the substrate below the protection liner; and
forming a connection element in the single-sided recess, the connection element electrically connecting the conductive line and the substrate.

18. The method of claim 17, wherein forming the single-sided structure comprises:
implanting ions at an oblique angle into the silicon-based layer to form implanted and un-implanted regions of the silicon-based layer at the bottom of the recess; and
removing the un-implanted region of the silicon-based layer.

19. The method of claim 17, wherein forming the single-sided structure comprises:
forming a transfer spacer on sidewalls of the protection liner; and
filling the trench with the fill material.

20. A precursor structure, comprising:
a trench formed in the substrate, the trench having sidewalls and a bottom region;
an encapsulation layer arranged along the sidewalls;
a conductive line arranged in the bottom region of the trench adjacent to the encapsulation layer;
a protection liner arranged adjacent to the encapsulation layer above the conductive line;
an opening in the encapsulation layer arranged along one of the trench sidewalls below the protection liner; and
an electrical connection formed between the substrate and the conductive line through the opening in the encapsulation layer.

21. The semiconductor substrate of claim 20, wherein the semiconductor substrate further comprises a single-sided structure arranged adjacent a recess formed in the trench, the recess vertically extending along one of the trench sidewalls to the conductive line, the single-sided structure covering the encapsulation layer arranged adjacent the opposing trench sidewall.

22. The semiconductor substrate of claim 20, wherein the single-sided structure comprises a carbon-based material.

23. The semiconductor substrate of claim 20, wherein the trench has an aspect ratio greater than or equal to approximately 6.0.
